(19) United States
(12) Patent Application Publication
(10) Pub. No.: US 2017/0146203 A1
(43) Pub. Date: May 25, 2017

(54) LIGHTING PANEL AND A LIGHTING SYSTEM

(71) Applicant: PanelOled Ltd., Central (HK)

(72) Inventors: Nicolas Joel Christian Belaidi, Central (HK); Peter Alexander Duddek, Central (HK)

(73) Assignee: PanelOled Ltd.

(21) Appl. No.: 15/349,046

(22) Filed: Nov. 11, 2016

(30) Foreign Application Priority Data
Nov. 20, 2015 (HK) 15111483.4

(51) Int. Cl. F21S 2/00; H01L 25/04; F21V 23/00; H05B 33/08; F21V 21/005; F21V 23/06

(52) U.S. Cl. CPC F21S 2/005; F21V 21/005; F21V 23/06; F21V 23/005; H05B 33/0896; H01L 25/048; F21W 2131/406

(57) ABSTRACT

A lighting panel includes a body having a first side and a second side opposed to each other, the body including a skeleton frame including a plurality of openings, one or more light emitting elements positioned on the first side of the body and on the skeleton frame, each of the one or more light emitting elements positioned within one of the plurality of openings, the one or more light emitting elements are solid state light emitting devices, a controller in electronic communication with the one or more light emitting elements, the controller configured to receive a control signal, process the received control signal and provide an illumination signal to the one or more light emitting elements to individually activate the one or more light emitting elements, a coupling arrangement positioned on the second side of the body, the coupling arrangement structured to allow removable connection with another lighting panel.

### TECHNICAL FIELD

The present invention relates to a lighting panel and a lighting system that includes two or more lighting panels being removably coupled together, wherein the lighting panel comprises one or more light emitting elements. The prior Short-term Patent Application No. 15111483.4 filed 20 Nov. 2015 in the Patents Registry of Hong Kong, from which foreign priority is claimed under 35 U.S.C. 119, is hereby incorporated by reference.

### BACKGROUND

Lighting systems are commonplace in modern society and used in a wide number of applications. Some examples are in staging, in theatres, film sets, stadiums and so on. Halogens and LEDs are commonly used in current lighting systems for staging and theatres. Such lighting systems can be heavy, bulky and require a significant amount of electrical power to operate.

### SUMMARY OF THE INVENTION

In accordance with an aspect, the present disclosure relates to a lighting panel comprising:
a body, the body comprising a first side and a second side, the first and second sides being opposed to each other,
the body including a skeleton frame, the skeleton frame including a plurality of openings,
one or more light emitting elements positioned on the first side of the body and on the skeleton frame, each of the one or more light emitting elements positioned within one of the plurality of openings,
the one or more light emitting elements are solid state light emitting devices,
a controller in electronic communication with the one or more light emitting elements, the controller configured to receive a control signal, process the received control signal and provide an illumination signal to the one or more light emitting elements to individually activate the one or more light emitting elements, and
a coupling arrangement positioned on the second side of the body, the coupling arrangement structured to allow removable connection with another lighting panel.

In some configurations the light emitting elements are arranged in a matrix comprising two or more rows of light emitting elements and two or more columns of light emitting elements. As such, the matrix may be a structure having a form of a rectangular array of cells.

In some configurations the panel comprises a total of sixty four light emitting elements arranged in the matrix, the one or more light emitting elements being arranged in an 8×8 matrix arrangement.

In some configurations the light emitting elements are arranged such that the beam angle of light generated by the light emitting elements is least 180°.

In some configurations the solid state light emitting devices are organic light emitting diodes.

In some configurations the coupling arrangement comprises one or more elongate struts, the one or more elongate struts being disposed on the second side of the body.

In some configurations the coupling arrangement comprises a first strut and a second strut, each strut being disposed on the second side of the body, the second strut being spaced from the first strut, each of the first strut and second strut including an attachment opening located at each end of each of the first strut and the second strut.

In some configurations the attachment opening comprises a pair of slots, each slot of the pair of slots extending outwardly from the attachment opening, each slot of the pair of slots extending in an opposite direction to the other slot of the pair of slots.

In some configurations the first strut includes two attachment openings, the second strut includes two attachment openings, and the attachment openings on the first strut align with the attachment openings on the second strut.

In some configurations the first strut and the second strut are telescoping, such that the first strut and second strut are length extendable.

In some configurations the first strut and the second strut include a magnetic material disposed on the first strut and the second strut respectively.

In some configurations the panel comprises a mounting arrangement, the mounting arrangement shaped and configured to allow the panel to be mounted to a structure.

In some configurations mounting arrangement is removably connected to the coupling arrangement.

In some configurations the mounting arrangement comprises a U shaped bracket, the U shaped bracket comprises an orifice and a swivelable hook, the swivelable hook connected to the orifice and the swivelable hook configured to mount the panel on a structure.

In some configurations the U shaped bracket is removably connected to the first strut and second strut, the U shaped bracket is removably connected to the first strut and the second strut via a fastener.

In some configurations the controller comprises a data unit, a power unit and an interface unit, the data unit generating and providing an illumination signal to the one or more light emitting elements, the power unit generating and providing a power signal to the one or more light emitting elements.

In some configurations the controller comprises one or more data ports, the one or more data ports receive a data signal from an external source, the data signal encompassing information to illuminate one or more of the light emitting elements, the controller comprises one or more power ports, the one or more power ports receive a power signal from a power source.

In some configurations the data unit receiving the data signal and converting the data signal to the illumination signal.

In some configurations the lighting panel comprises a receptacle disposed on the second side, the receptacle housing and holding the controller within the receptacle.

In some configurations the first strut and second strut are connected to either side of the receptacle, the lighting panel comprises a pair of pegs, each peg of the pair of pegs connected to the receptacle and extending outwardly from the receptacle, the first strut and second strut connected to one of the pegs of the pair of pegs.

In some configurations the lighting panel weighs 5 kg or less, and the lighting panel comprises a volume of less than 0.0093 m³.

In some configurations the lighting panel is useful for exhibition lighting or stage lighting.

In accordance with a further aspect, the disclosure relates to a lighting system comprising;
two or more lighting panels, each lighting panel comprising one or more solid state light emitting elements, each lighting panel is as per any embodiment or configuration of the first aspect,
the lighting system is a modular system such that each lighting panel of two or more lighting panels is removably connectable to one or more other lighting panels.

In some configurations the lighting system comprises a controller assembly configured to control a light emitting element via a multichannel controller, wherein the multichannel controller comprises a plurality of control channels and each channel corresponding to each light emitting element.

In some configurations each lighting panel comprises a pair of struts, the struts including one or more attachment openings, the struts of each lighting panel being removably connectable to each other.

In some configurations the lighting system is suitable for use in exhibition lighting or stage lighting applications.

In accordance with a further aspect, the present disclosure relates to a lighting panel, the lighting panel comprising,
a body having a first side and a second side, the body being defined by an aluminium skeleton frame, the skeleton frame comprises a plurality of openings,
one or more light emitting elements positioned on the first side of the body and on the skeleton frame, each of the one or more light emitting elements positioned within one of the plurality of openings,
the one or more light emitting elements being organic light emitting diodes,
the light emitting elements are arranged in matrix, the lighting panel comprises a total of sixty four light emitting elements arranged in the matrix, the one or more light emitting elements being arranged in an 8×8 matrix arrangement,
the light emitting elements are arranged such that the beam angle of light generated by the light emitting elements 180°,
a controller in electronic communication with the one or more light emitting elements, the controller configured to receive a control signal, process the received control signal and provide an illumination signal to the one or more light emitting elements to individually activate the one or more light emitting elements,
a coupling arrangement positioned on the second side of the body, the coupling arrangement structured to allow removable connection with another lighting panel, the coupling arrangement comprises a first strut and a second strut, each strut being disposed on the second side of the body, the second strut being spaced from the first strut, each of the first strut and second strut including an attachment opening located at each end of each of the first strut and the second strut,
the attachment opening comprising a pair of slots, each slot of the pair of slots extending outwardly from the attachment opening, each slot of the pair of slots extending in an opposite direction to the other slot of the pair of slots,
the first strut includes two attachment openings, the second strut includes two attachment openings, the attachment openings on the first strut aligns with the attachment openings on the second strut,
the panel comprises a mounting arrangement, the mounting arrangement shaped and configured to allow the panel to be mounted to a structure, the mounting arrangement comprises a U shaped bracket, the U shaped bracket comprises an orifice and a swivelable hook, the swivelable hook connected to the orifice and the swivelable hook configured to mount the panel on a structure, the U shaped bracket is removably connected to the first strut and second strut, the U shaped bracket is removably connected to the first strut and the second strut via a fastener,
the controller comprises a data unit, a power unit and an interface unit, the data unit generating and providing an illumination signal to the one or more light emitting elements, the power unit generating and providing a power signal to the one or more light emitting elements,
the controller comprises one or more data ports, the one or more data ports receive a data signal from an external source, the data signal encompassing information to illuminate one or more of the light emitting elements, the controller comprises one or more power ports, the one or more power ports receive a power signal from a power source, the data unit receiving the data signal and converting the data signal to the illumination signal,
the lighting panel further comprising a receptacle disposed on the second side, the receptacle housing and holding the controller within the receptacle, and;
wherein the lighting panel weighs 5 kg or less, and the lighting panel comprises a volume of less than 0.0093 m³.

The term “comprising” (and its grammatical variations) as used herein are used in the inclusive sense of “having” or “including” and not in the sense of “consisting only of”. Unless the context clearly requires otherwise, throughout the description and the claims, the words “comprise”, “comprising”, and the like, are to be construed in an inclusive sense as opposed to an exclusive or exhaustive sense, that is to say, in the sense of “including, but not limited to.”

### BRIEF DESCRIPTION OF THE DRAWINGS

FIG. 1 shows a perspective view of an embodiment of a lighting panel.

FIG. 2 shows a front view of the lighting panel of FIG. 1.

FIG. 3 shows front view and a side view projection of the lighting panel of FIG. 1.

FIG. 4 shows a detailed view of one OLED pane.

FIG. 5 shows a detailed view of an electrode arrangement across two OLED panes.

FIG. 6 shows an example of a circuit layout that interconnects the electrodes associated with each OLED with a power source.

FIG. 7 shows a rear perspective view of the lighting panel as per FIG. 1.

FIG. 8 shows a schematic diagram of the controller.

FIG. 9a shows a receptacle that is disposed on the lighting panel and houses the controller and its components shown in FIG. 8.

FIG. 9b shows a detailed view of the struts and receptacle attachment.

FIG. 10 shows a close up view of an end of a strut and details of an attachment opening located on the strut.

FIG. 11 shows details of a mounting arrangement and a bracket that forms part of the mounting arrangement.

FIG. 12 shows an embodiment of a lighting system that comprises at least two lighting panels.

### DETAILED DESCRIPTION

Lights and lighting panels are becoming more and more prevalent in modern uses. The entertainment industry is an industry where lighting panels are used extensively. The use of electronic control, in particular digital control, has allowed users to provide greater possibilities of controlling lighting panels. The use of modern digital control has also allowed users to create more elaborate lighting displays. Current lighting panels used in the entertainment industry are often bulky, heavy and difficult to assemble. The current lighting panels are often standalone panels and do not easily connect to other lighting panels. Some examples of current lighting panels are Jarag Halogen panels or Jarag LED or Elidy LED panels. These panels are often too heavy, cumbersome to use and are difficult to interconnect to other panels. These known lighting panels are therefore relatively inflexible in use. The use of LEDs or halogen lamps causes glare and also consume relatively high power in use.

The present disclosure relates to a lighting panel that is particularly suitable for use in exhibition lighting or stage lighting applications due to its light weight, lower power consumption, increased beam angle of light and UV free light. The lighting panel as disclosed herein is also particularly useful since it can easily be connected to other lighting panels to create a modular lighting system. The present disclosure relates to a lighting panel and a lighting system comprising multiple lighting panels that ameliorates some of the problems with current lighting panel.

The present disclosure relates to a lighting panel comprising a plurality of light emitting elements with a coupling arrangement that is configured to allow one or more lighting panels to removably couple together. The lighting panel also comprises a controller assembly configured to control the activation of the light emitting elements. In one configuration the coupling arrangement mechanically couples two or more lighting panels together. In another configuration the coupling arrangement is configured to mechanically couple the panels together and electrically couple the light emitting elements of each lighting panel to the controller assembly such that a single controller assembly can control the activation of any one or more light emitting elements. In some configurations the controller assembly comprises a digital multichannel controller that independently controls each light emitting element, and wherein each light emitting element is associated with a channel in the multichannel controller.

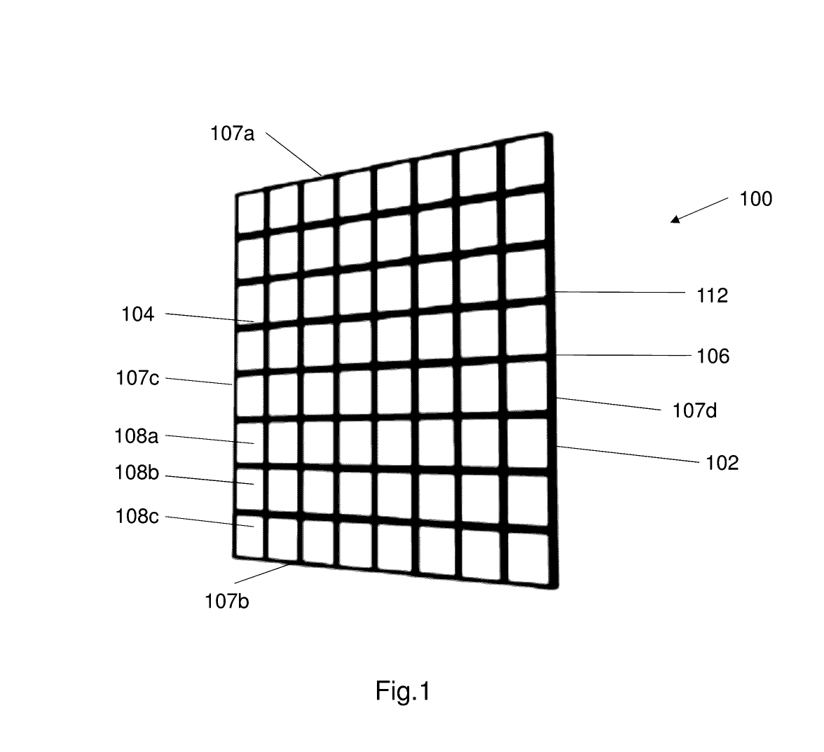

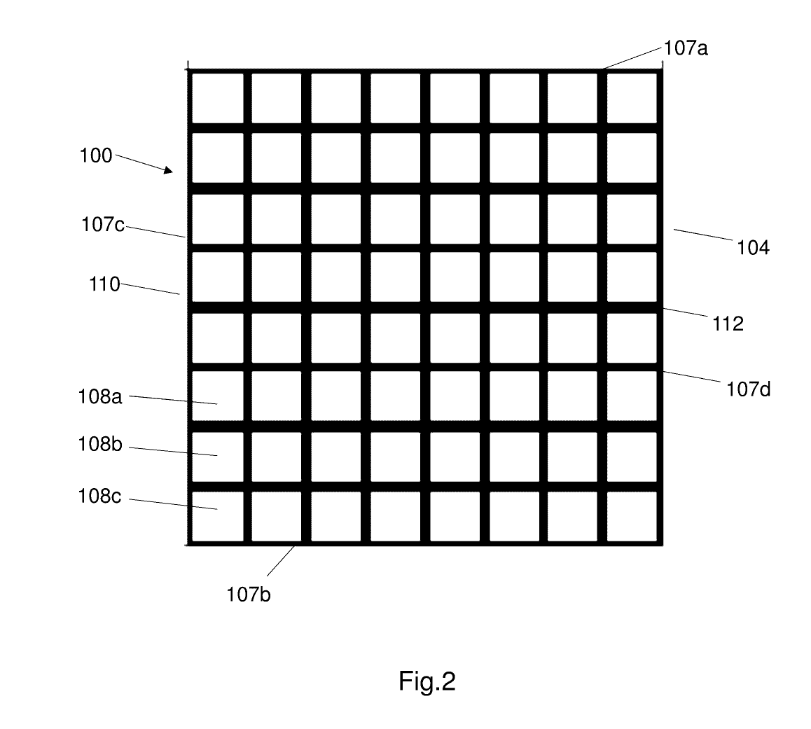

FIGS. 1 to 4 illustrate a lighting panel 100. The lighting panel 100 comprises a body 102 with a first side 104 and a second side 106. The first side 104 and second side 106 are opposed to each other. In use, the first side 104 is considered the front side, meaning it is the side that is readily visible to users or spectators or people. The first side 104 is the front side when the lighting panel 100 is in use. The second side 106 is the rear or back side of the lighting panel. As per FIGS. 1 and 2, the panel 100 comprises a pair of transverse edges and a pair of longitudinal edges that define the shape of the panel 100. The panel comprises a first transverse edge 107a (top edge), a second transverse edge 107b (bottom edge), a first longitudinal edge 107c (left edge) and a second longitudinal edge 107d (right edge). The terms top, bottom, left and right are considered when viewing the panel from the first side (i.e. front side). The edges 107a, 107b, 107c, 107d define the outer bounds of the panel. In the illustrated configuration the panel 100 is of a rectangular shape. In alternative configurations the panel 100 may be any other suitable regular polygon shape, such as for example a square or pentagon or rhombus or parallelogram shaped and so on. The panel 100 may comprise additional edges to define a polygon shape.

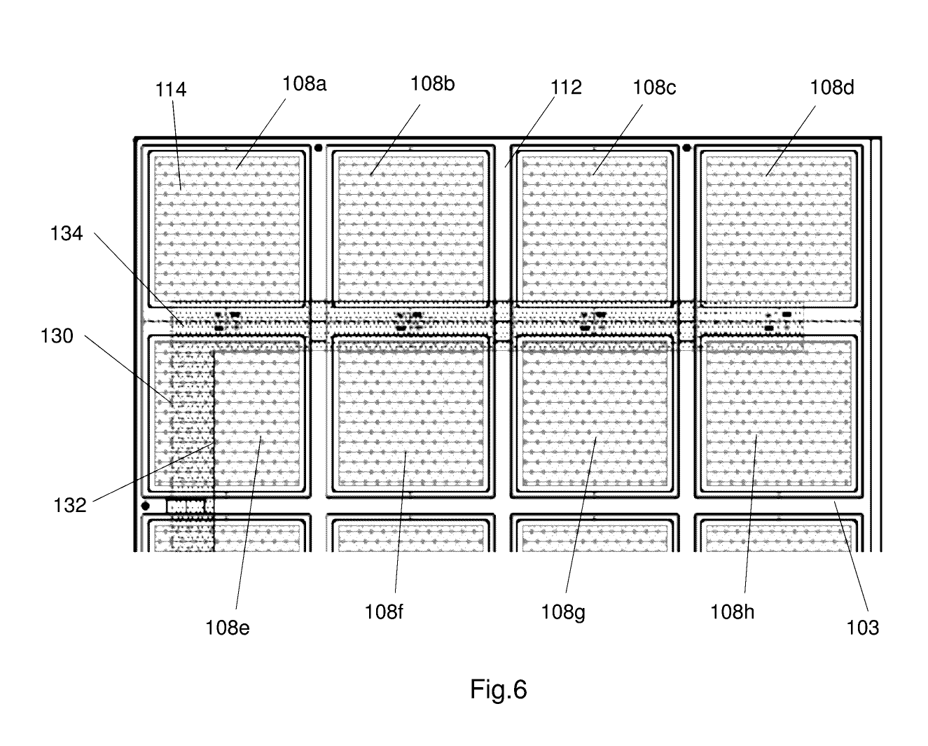

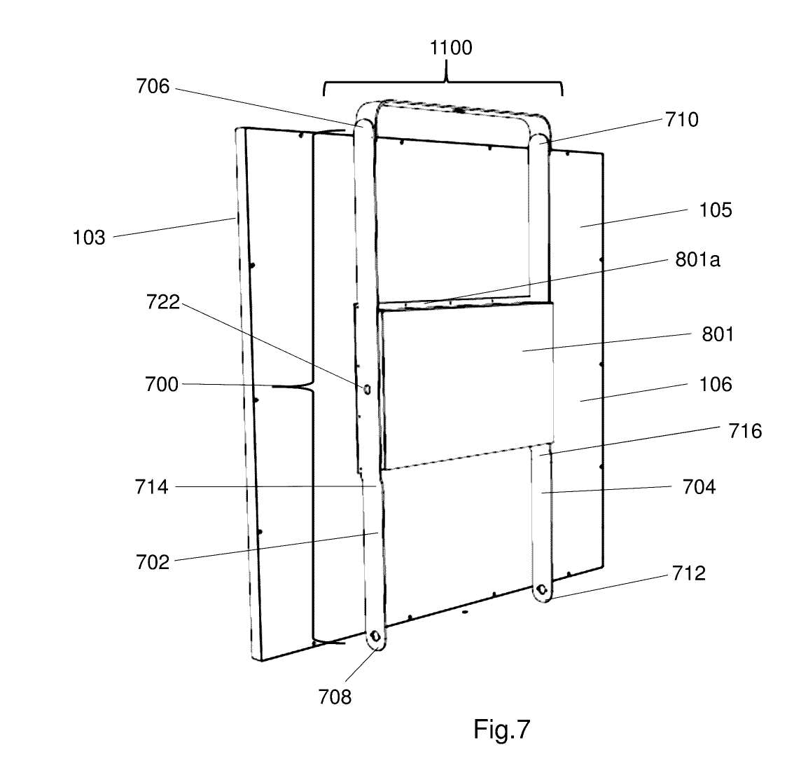

The panel comprises a skeleton frame 103 as shown in FIGS. 6 and 7. The body 102 is defined by the skeleton frame 103. The skeleton frame 103 comprises a frame work with a plurality of openings such as the openings shown. The skeleton frame 103 provides a rigid structure to support the light emitting elements (described later). The openings in the skeleton frame 103 provide space to accommodate the one or more light emitting elements. The skeleton frame 103 forms the matrix 110 for the light emitting elements. The panel comprises a planar back panel 105 that is disposed on the second side. The back panel 105 is in the form of a continuous sheet. The skeleton frame 103 and back panel are formed from a suitable metal such as aluminium or stainless steel. Aluminium and stainless steel are useful because these metals are light and rust resistant. The body 102 and skeleton frame 103 can be formed by any suitable method such as casting, stamping, machining and so on. In alternative forms the skeleton frame 103 may be formed of a rigid plastic such as polycarbonate to provide a lighter panel 100. The frame 103 can be moulded or vacuum formed from plastic.

The lighting panel 100 comprises one or more light emitting elements positioned on the first side 104 of body 102. The light emitting elements are positioned on and supported by the skeleton frame 103. For ease of description only three lighting elements are referred to with reference numerals 108a, 108b, 108c, but it should be understood that any description regarding light emitting elements relates to all the light emitting elements of the lighting panel 100. Each square pane is a single light emitting element. The light emitting elements, such as 108a, 108b, 108c are solid state light emitting elements. In the illustrated embodiments the light emitting elements 108a, 108b, 108c, of the lighting panel 100 are organic light emitting diodes (OLEDs). The light emitting elements 108a, 108b, 108c are preferably active matrix type OLED devices i.e. AMOLED devices. Alternatively PMOLED device may be used for the light emitting elements 108a-108c. The OLEDs align with the openings in the skeleton frame 103. The panel 100 comprises the same number of light emitting elements as openings in the skeleton frame 103.

FIG. 2 shows more details of the light emitting elements 108a-108c arrangement on the lighting panel 100. The light emitting elements are arranged in a matrix 110 on the lighting panel 100. FIG. 2 illustrates shows one exemplary embodiment of the matrix 110. The matrix 110 comprises a plurality of rows and columns. In the illustrated embodiment the OLEDs are arranged in an 8×8 matrix 110. The matrix comprises 8 rows and 8 columns of light emitting elements. The matrix 110 comprises a total of 64 OLEDs in a single lighting panel 100. Each cell i.e. each square pane corresponds to a single light emitting element. The matrix 110 and panel 100 are a square shape. Alternatively the matrix and panel may be a rectangular shape.

Alternative configurations light emitting elements are also contemplated as part of this disclosure. For example in other, non-illustrated configurations the panel 100 may comprise a 2×2 or 3×3 or 4×4 or any other square OLED configuration. In a further non-illustrated configuration the panel may comprise a 2×8 or 3×8 or 4×8 or any other rectangular OLED configuration.

The OLEDs used on the panel 100 are any suitable polygon shape. In the illustrated configurations the OLEDs are square shaped panes. However OLEDs of different shapes such as rectangles or triangles or any other polygon shape are also possible to use. The OLEDs may be arranged in a shape that corresponds to the shape of the panel 100. The matrix 110 can be shaped to correspond or match the shape of the panel 100. This is because OLEDs are formed of a flexible organic material that can be cut or formed into any suitable polygon shape. This provides greater flexibility and greater options with respect to the type of shape used for the light emitting devices.

Prior art lighting panels such as ones that use LEDs or halogen bulbs are limited to the relatively circular or cylindrical shaped light emitting element that is used. OLEDs allow a user to use any shaped light emitting element.

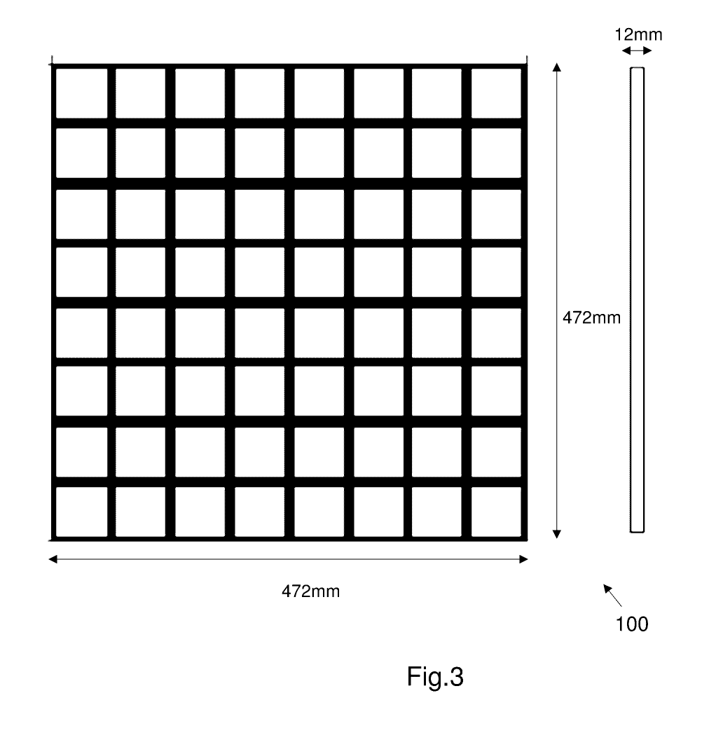

FIG. 3 shows an exemplary panel 100 and the dimensions of the exemplary panel 100. FIG. 3 shows a front view and a side view of the panel 100. As per the illustrated example, the panel 100 has a height of 472 mm, a width of 472 mm and a thickness of 12 mm. Other sized panels are contemplated. The volume of the illustrated panel is 2673408 mm³. The volume of the lighting panel 100 is less than 0.0093 m³. The exemplary panel 100 illustrated in FIGS. 1 and 2 has a weight of less than 5 kg.

The body 102 is constructed of a plurality of layers of material. The body 102 comprises a base layer 112. The base layer 112 is formed from a material that is rigid and light, such as for example aluminium. The skeleton frame 103 comprises the base layer 112. Other examples of materials used to form the base layer are plastics or glass or acrylic material. The OLEDs 108a, 108b, 108c and so on are disposed on the base layer 112.

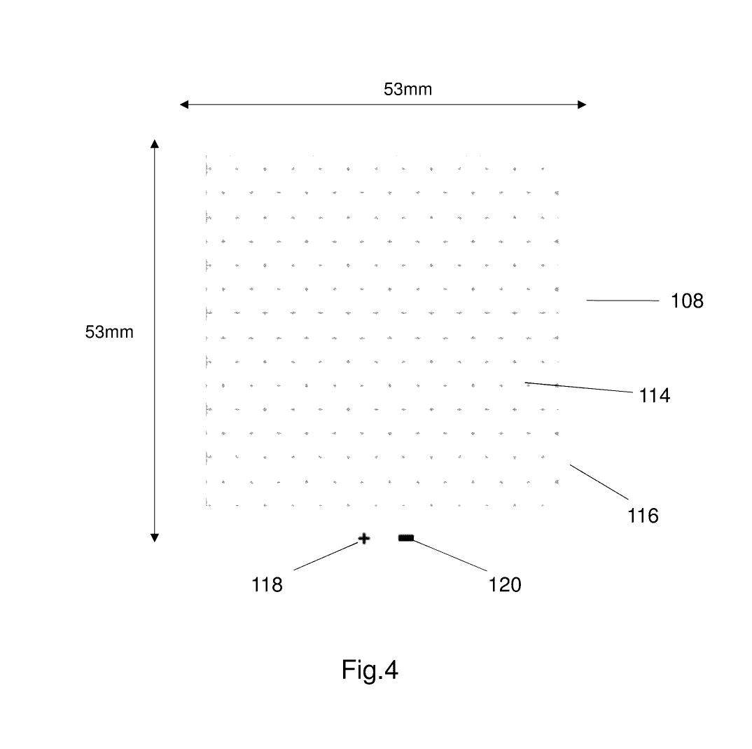

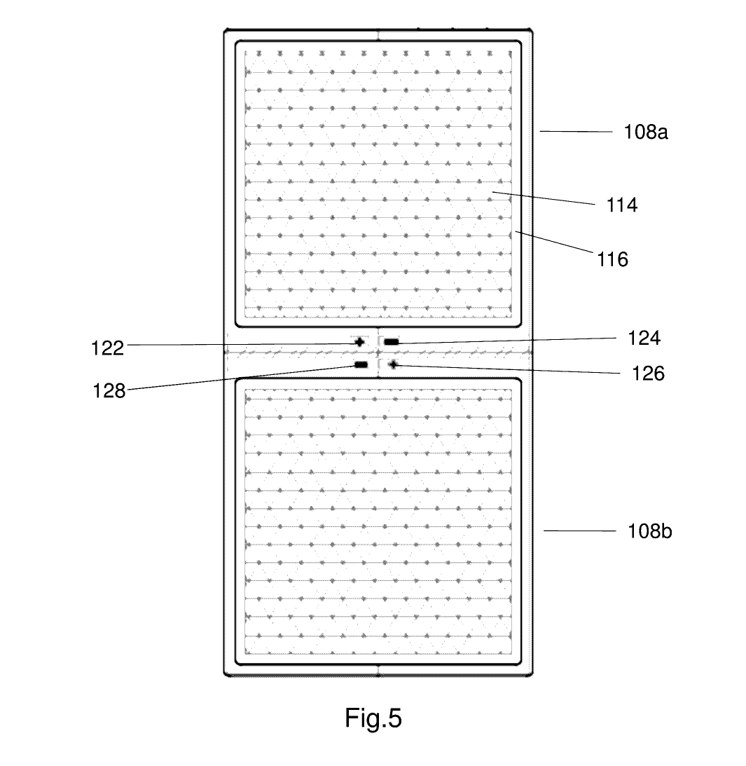

The OLED arrangement will be described in more detail in reference to FIGS. 4 and 5. FIG. 4 shows details of a single OLED pane 108. The OLED pane 108 comprises a laminate structure of multiple materials. The OLEDs comprise at least a layer of electroluminescent layer 114 of organic compound that emits light in response to the application of an electrical current and a flexible plastic substrate 116. The hatched area shown in FIG. 4 comprises the electroluminescent layer 114. The clear layer surrounding the electroluminescent layer denotes the flexible substrate 116.

The OLED pane 108 (and all the OLEDs) are flexible and bendable. Alternatively the OLEDs may be substantially in-flexible and may hold their shape. Such in-flexible OLEDs may be formed from an electroluminescent layer of organic compound disposed on a glass substrate. The panel 100 comprises flexible OLEDs but alternatively in-flexible OLEDs may be used on the panel 100. All the OLEDs used in the lighting panel 100 are constructed as described herein.

The OLED pane 108 comprises a pair of electrodes 118, 120 that are connected to the OLED pane 108. The electrodes include an anode 118 and a cathode 120. The electrodes supply a voltage to the electroluminescent layer to cause the electroluminescent layer to illuminate and emit a light. The OLED pane is a 9 Volt, 0.04 Amp and 0.35 Watts rated OLED. Other types of OLEDs are also contemplated for use in the lighting panel 100.

The OLED pane 108, as illustrated in FIG. 4, is a square shaped pane. The illustrated OLED pane 108 has a height and width of 53 mm. The substrate 116 extends an equal width beyond the electroluminescent layer 114. Alternatively the OLED pane 108 may be any other polygon shaped as discussed earlier. The OLED pane 108 is only a few millimetres thick. The OLEDs 108 occupy a small footprint because the thickness is only a few millimetres. The substrate 116 is attached to the skeleton frame 103.

FIG. 5 shows a further embodiment of the electrode arrangement for across two OLED panes 108a, 108b. FIG. 5 shows a first and second OLED pane 108a, 108b arranged adjacent each other. As shown in FIG. 5 each pair of OLEDs the anode and cathodes are arranged in opposing pairs. A first pair of electrodes associated with the first OLED 108a are labelled 122 (first anode) and 124 (first cathode). The electrodes associated with the second OLED 108b are labelled 126 (second anode) and 128 (second cathode). As seen in FIG. 5 the first anode 122 and first cathode 124 are positioned adjacent each other and complete an electrical circuit across the first OLED pane 108a. The first anode 122 and first cathode 124 provide a current to the electroluminescent layer of the first OLED 108a to cause the first OLED 108a to illuminate when energised. The second anode 126 and second cathode 128 are positioned adjacent each other, and complete an electrical circuit across the second OLED 108b. The second anode 126 and second cathode 128 provide a current to the electroluminescent layer of the second OLED 108b to cause the second OLED 108b to illuminate when energised. As shown in FIG. 5, the first anode 122 is positioned adjacent the second cathode 128 and the first cathode 124 is positioned adjacent the second anode 126. Such an arrangement provides a complete circuit between the two OLEDs 108a, 108b.

FIG. 6 shows an example of a circuit layout that interconnects the electrodes associated with each OLED with a power source. FIG. 6 shows eight OLEDs 108a-108h, positioned adjacent each other. Each OLED comprises an associated anode and cathode. The anode and cathode of each OLED pair are arranged in an opposed pair arrangement similar to that described in FIG. 5. The lighting panel comprises at least pair of electronic traces that electrically connect with the anode and cathode of each OLED. The electronic traces are in electrical communication with the OLEDs via the electrodes associated with the OLED. FIG. 6 shows a pair of electronic traces 130, 132 that are disposed on the base layer 112. The traces 130, 132 are formed from copper and deposited on the base layer 112. The traces 130, 132 are placed on the base layer 112 by any suitable process such as electrodepositing, adhesion, etching or any other suitable process. The traces 130, 132 made of any electrically conductive material. In a preferred form the body 102 comprises a PCB 134 (printed circuit board) layer positioned on the base layer 112. The PCB layer comprises a substrate such as a silicone substrate with electronic traces etched or deposited onto the PCB layer 134. The OLEDs 108a-108h are disposed on the PCB layer. The PCB layer may comprise a substrate made of any other suitable material such as fibreglass or plastics. The PCB layer 134 is disposed in the skeleton frame 103.

The panel 100 comprises a plurality of PCBs that electrically connect a plurality of OLEDs and associated electrodes of the OLEDs. In one embodiment one PCB interconnects eight OLEDs together. Therefore the illustrated embodiment of the panel 100 comprises eight discrete printed circuit boards, since the panel 100 comprises 64 total OLEDs. The PCBs are in electrical communication with a controller 800. The controller 800 is configured to provide a power signal to power the OLEDs and an illumination signal to activate one or more of the OLEDs on the panel 100.

FIG. 7 shows a rear view of the panel 100. FIG. 7 shows a view of the panel 100 from the second side 106. FIG. 7 shows a back panel 105 that is attached to the rear of the skeleton frame 103 and defines the second side 106 of the panel 100. The back panel 105 may be formed from aluminium or stainless steel. Alternatively the back panel 105 may be formed from a plastics material or wood. The back panel 105 provides a closure to enclose the rear side of the skeleton frame 103. The back panel 105 is attached to the frame 103 by screws or rivets or by welding or may be glued by an adhesive.

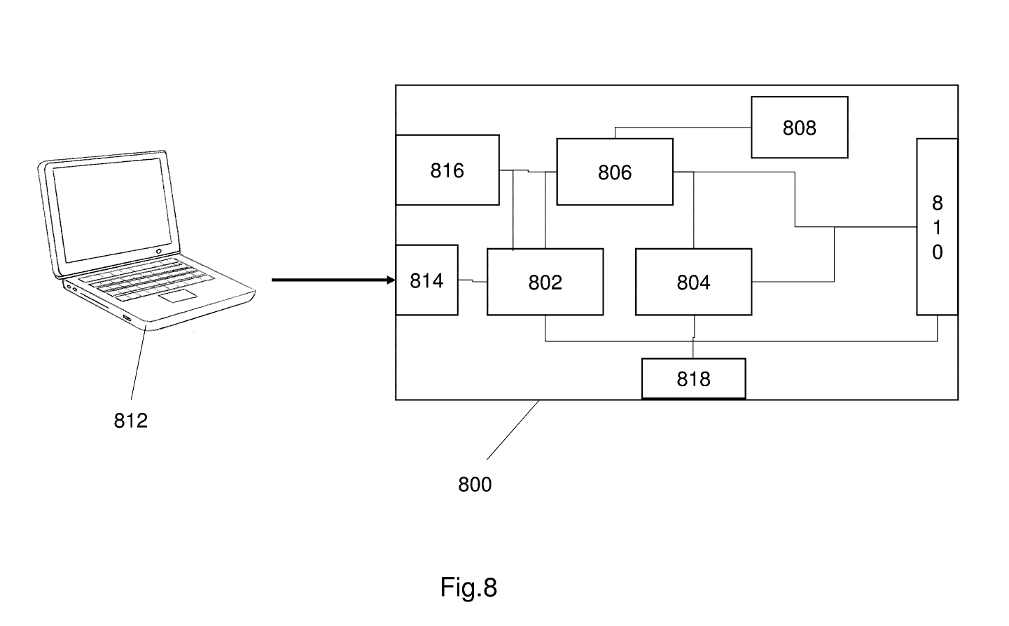

FIG. 7 shows a receptacle 801. The receptacle 801 is in the form of a box. The receptacle houses the controller 800 and associated electronics of the controller 800. FIG. 8 shows a schematic diagram of the controller 800. The controller 800 comprises a data unit 802 and a power unit 804. The data unit 802 generates an illumination signal. The power unit 804 generates a power signal. The illumination signal comprises information regarding which OLED is to be activated. The power signal is a 9 volt power signal. The controller further comprises a processor 806 configured to control the data unit 802 and power unit 804. The processor 806 may be configured to receive the illumination signal and the power signal and combine the two signals into a common signal that can be transmitted to the OLEDs to power the OLEDs and illuminate specified OLEDs within the matrix 110. The controller 800 further comprises a memory unit 808 that is communication with at least the processor 806. The memory unit 808 may be a RAM, ROM or a flash memory. Preferably the memory unit 808 is a read and write flash memory.

The data unit 802 is a hardware module implemented within the controller 800. In one embodiment the data unit 802 may be a hardware module that is part of the processor 806 or controlled by the processor 806. Alternatively the data unit 802 may be a software module. The data unit 802 may be stored as a set of executable instructions in a non-transitory computer readable medium such as the memory unit 808. The power unit 804 is implemented as a hardware module that is part of the processor 806 or controlled by the processor 806. Alternatively the power unit 804 may be implemented as a software module.

The power unit 804 may be stored as a set of executable instructions in a non-transitory computer readable medium such as memory unit 808.

The data unit 802 is configured to receive a data signal from an external source 812 such as a laptop, or mobile device or computer. The external source 812 includes appropriate software or a computer program that allows control of OLEDs. Some example protocols to control the OLEDs 108a-108c are DMX or Artnet. The data unit 802 is configured to receive a data signal from the external source in any suitable format, such as for example DMX or Artnet. The data unit 802 processes the data signal and generates a corresponding illumination signal that is transmitted to the OLEDs and illuminates one or more selected OLEDs in accordance with the data signal. The data signal includes information regarding which OLED to illuminate and may also include data regarding the brightness or intensity of illumination. The data signal also includes information regarding the tone or shade of the OLED. OLEDs generally produce light in the warm light to daylight range. The data signal includes information regarding the tone of the OLED output.

The controller comprises a data port 814 provided in the controller receptacle 801. The data port 814 is in electronic communication with the data unit 802. The external source 812 can be directly connected to the data port 814 via a data cable. The data port 814 communicates the received signals, from the external source 812, to the data unit 802. The data signals can be provided to the data unit 802 through an appropriate wired connection received by the data port 814.

In another embodiment the controller 800 may comprise multiple input ports. The controller 800 may comprise an input port that corresponds to or relates to a particular data signal format or protocol. For example the controller 800 comprises a first data port dedicated to receive a DMX data input and second data port to receive an Artnet data input. Both data ports are in communication with the data unit 802.

In a further embodiment the controller 800 may comprise a wireless communication interface 816. The wireless communication interface may be a WIFI module that allows wireless communication between the external source and the controller 800, and more specifically the data unit 802. The wireless interface 816 creates a Wi-Fi enabled panel 100. This is advantageous because a user can control and communicate with the panel 100 using a WIFI network. Other wireless communication protocols may be used to provide data to the controller 800.

Each OLED 108a-108c can be controlled individually using the DMX or Artnet protocols. The DMX protocol assigns an individual channel to each OLED and hence 64 channels exist for the exemplary OLED panel 100, as per the figures. The data signal received from the external source 812 comprises information regarding which channel is to be activated or illuminated. The data unit 802 converts the received data signal into an illumination signal that is provided to the OLEDs, to illuminate the specifically identified OLED.

The Artnet protocol assigns a unique address to each OLED. The data signal provided to the data unit 802 identifies the OLED that is to be illuminated or activated by the unique address. The address can be IP addresses for the WIFI enabled embodiment. The data unit 802 generates an illumination signal corresponding to the received data signal and provides the illumination signal to the OLEDs that are to be illuminated based on the data signal.

The DMX and Artnet protocols are well known control protocols for stage lighting fixtures. The same protocols can be used to for controlling and providing data to OLEDs in a lighting panel 100. The use of DMX or Artnet provides a more flexible control scheme. The use of DMX and Artnet protocols provide for easier control and allows for individual control of each OLED of the panel 100. Any other suitable protocols can be used to control the activation and illumination of the OLEDs 108a-108c.

The controller 800 includes a power port 818 provided in the receptacle 801. The power port 818 is in electrical communication with power unit 804. A power source can be connected to the power port 818 to supply power to the OLED panel 100. The power received from an external power source, is converted into a 9 volt, constant current signal by the power unit 804 and provided to the OLEDs 108a-108c. One example is a powercon input. The power supplied to the power unit 804 can be a standard voltage such as a 120 or 240 volt AC supply. The power unit 804 comprises appropriate circuitry and components to generate the power signal. In a further example the power signal may be supplied by the external source 812.

In alternative embodiments the power unit 804 may be a driver unit or a battery source that generates power. For example the power unit 804 may be in the form of a 12 volt battery or a 120/240 volt driver unit. In a further alternative embodiment the receptacle 801 may include a battery of a power source disposed within the receptacle 801, and in electrical communication with at least the power unit 804.

The controller 800 further comprises an interface unit 810. The interface unit 810 comprises an interface circuit that electrically connects with the PCBs. The interface unit 810 receives the date signal from the data unit 802 and the power signal from the power unit 804. Alternatively the interface unit 810 receives a signal from the processor 806 that comprises a component corresponding to the data signal and a component corresponding to the power signal. The interface unit 810 provides the power and data signal to the PCBs and hence to the OLEDs to power the OLEDs and illuminate the OLEDs. The interface unit 810 may comprise a plurality of channels, the number of channels being equal to the number of light emitting elements (i.e. OLEDs) on the panel.

The controller 800 further provides a dimmer function that allows a user to selectively vary the intensity or brightness of light emitting elements. In particular the controller 800 provides a user the ability to vary the brightness or intensity of the OLEDs 108a-108c. The data unit 802 can provide an illumination signal that encompasses information regarding the brightness based on a data signal received from the external source 812. A user for example a DJ or a lighting engineer or any other user of the lighting panel can input which OLEDs to activate as well as define the brightness or intensity. The user can also input or implement a dimmer function through an appropriate interface implemented on the external source 812. The data unit 802 receives a data signal that contains the brightness information e.g. the dimming of certain OLEDs. The data unit 802 generates an illumination signal that comprises brightness information. The processor 806 receives the illumination signal from the data unit 802 and a power signal from the power unit 804. The processor 806 combines the illumination signal and the power signal into a signal that is transmitted to the OLEDs. The processor 806 modulates the power signal to correspond to the brightness information. The processor 806 is configured to implement the dimming information that is transmitted. Alternatively the interface unit 810 may be configured to modulate power levels based on brightness information or implement dimming information.

Alternatively the processor 806 is arranged to control the level of power supplied by the power unit 804. The level of power supplied by the power unit 804 relates to the brightness or intensity defined in the received data signal. In this alternative form the data unit 802 provides the processor 806 with the appropriate brightness information e.g. which OLEDs are required to be dimmed to a defined power level. The processor 806 controls the power unit 804 to ensure that the power level is modulated based on the brightness level defined.

The external source includes an appropriate software program being stored in a memory device of the external source and the program being executable by a processor of the external source 812. The program provides a user interface that allows a user to input information regarding which OLEDs to activate as well as the brightness. The interface also allows a user to input custom inputs such as messages, videos, pictures and any other visual information. The inputs are converted to a data signal in the appropriate protocol and transmitted to the controller 800, in particular the data unit 802. The memory 808 may function as a cache. The memory 808 can temporarily store information and transmit data as required. This provides further flexibility in the type of displays and the type of patterns that can be displayed on the OLED panel 100.

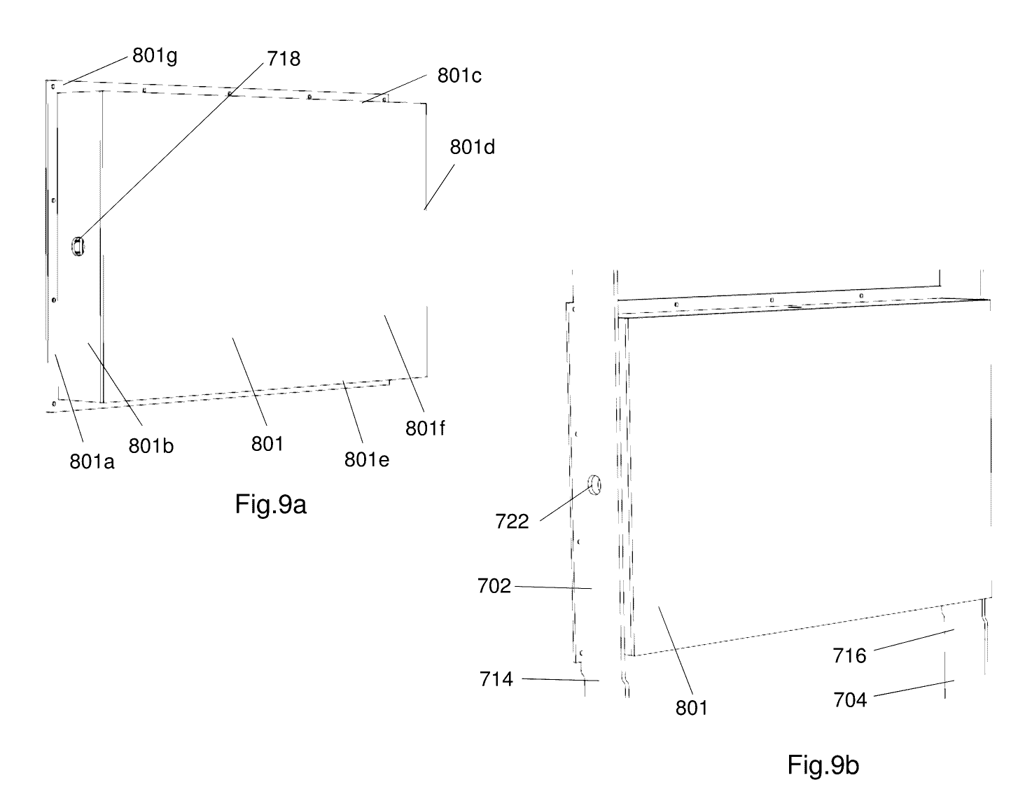

FIG. 9a shows a detailed view of the receptacle 801. The receptacle 801 is a substantially rectangular shaped enclosure that houses the controller 800 and its components. As shown in more detail in FIG. 9a, the receptacle 801 includes a base 801a and four upstanding walls 801b, 801c, 801d, 801e. The walls extend outward from the base 801a. The receptacle includes a cover 801f. The cover may be removably coupled to the vertical walls. The walls 801b-801e are at right angles to each other. The receptacle 801 includes a flange 801g extending about a base 801a of the receptacle 801. The flange 801g is connected to the rear side 106 of the panel 100 by a plurality of screws or welding or by an adhesive. The receptacle 801 is formed from a metal such as aluminium or stainless steel. The receptacle 801 may be formed from any other suitable metal that is light, substantially rigid and rust resistant.

Referring back to FIG. 7, the figure shows a coupling arrangement 700 that is disposed on the second side 106 of the panel 100. The coupling arrangement 700 is configured to removably couple the lighting panel 100 to another lighting panel 100 to create a lighting system. The coupling arrangement 700 allows for easy engagement and disengagement of one lighting panel to another lighting panel. The coupling arrangement 700 enables a modular lighting system. FIG. 7 illustrates a mounting arrangement 1100. The mounting arrangement 1100 is removably connectable to the coupling arrangement 700.

The mounting arrangement allows the lighting panel 100 to be mounted onto any appropriate structure. The mounting arrangement 1100 is further configured to allow a modular lighting system that comprises a plurality of lighting panels 100 connected together to be mounted on an appropriate structure.

The coupling arrangement 700 includes one or more struts disposed on the body 102. FIG. 7 shows a first strut 702 and a second strut 704 disposed on the second side 106 of the panel 100. The first strut 702 and second strut 704 are elongate in shape. The first strut 702 and second strut 704 are arranged in a vertical orientation. The first strut 702 comprises an upper end 706 and a lower end 708, the two ends are opposed to each other. The second strut 704 comprises an upper end 710 and a lower end 712, the two ends being opposed each other. The term upper and lower is referred to with reference to FIG. 7. The first strut 702 and the second strut 704 are identical to each other, as shown in FIG. 7. As shown in FIG. 7, the first strut 702 and second strut 704 are positioned on either side of the controller receptacle 801. The first strut 702 and the second strut 704 are arranged parallel to each other.

The first strut 702 and the second strut each include a bent section 714, 716 respectively. The bent section 714, 716 of each strut is located in the lower third of the strut. The bent section 714, 716 is located closer to the lower end of the strut. The bent section 714, 716 may be located half way down the strut. As illustrated in FIG. 7, the bent section 714, 716 is located two thirds a way down the strut. The bent section 714, of the first strut 702, offsets the lower end 708 from the upper end 706. The bent section 716, of the second strut 704, offsets the lower end 712 from the upper end 710.

FIG. 9b shows a detailed view of the strut 704, 706, and receptacle 801 attachment. The controller receptacle 801 includes a pair of outwardly extending pegs 718 and 720. As shown in FIG. 9a, a first peg 718 extends outwardly from a first upstanding wall 801b. A second peg 720 extends outwardly from the opposing upstanding wall 801d but is hidden. As shown in FIG. 9b, the first strut 702 comprises an aperture 722 located approximately half way along the strut 702. The aperture 722 is located adjacent the bent section 714. The second strut 704 also includes an aperture 724 (hidden in FIG. 9b) that is positioned adjacent the bent section 716. The pegs 718 and 720 are located within the apertures 722 and 724 respectively. FIG. 9b shows the peg 718 being positioned within the aperture 722. The strut 704 is connected to the receptacle 801 via the hidden peg 720. Each strut 702 and 704 can rotate or pivot about each peg 718, 720 respectively. Note again that the peg 720, and aperture 724 are hidden and are not illustrated on the figures on account of the perspective views presented.

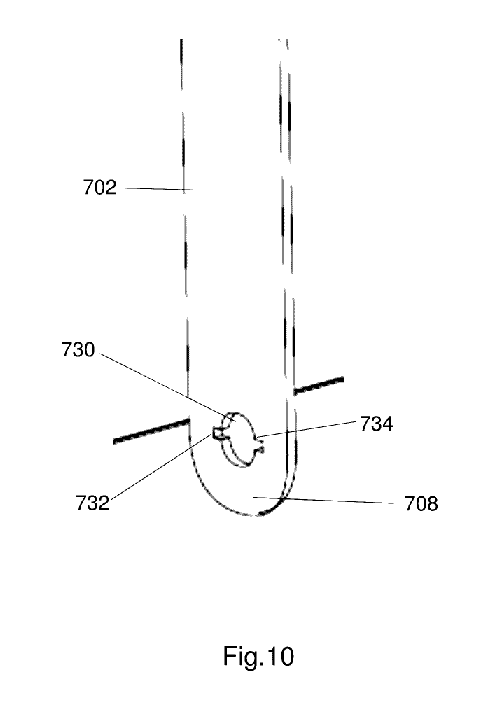

FIG. 10 shows a more detailed view of the lower end 708, of the first strut 702. The lower end 708 comprises an attachment opening 730 positioned at or adjacent the lower end 708 of the first strut 702. The attachment opening 730 includes a pair of slots 732, 734. The slots 732, 734 extend outwardly from the opening 730. The slots 732, 734 extend in opposite directions to each other. The second strut 704 also comprises an opening with two slots extending in opposing directions, which are not shown for clarity. Each end of each strut includes the attachment opening 730 with a pair of slots 732 and 734, as disclosed. A complementary shaped fastener can be inserted into the opening when coupling a first panel and second panel together. The fastener is preferably a quick mount fastener that can be attached and detached from the opening. Alternatively a nut and bolt assembly or a wing nut may be used to removably couple a first panel and second panel together. The panels are coupled together by coupling the struts of one lighting panel to the respective struts of the second lighting panel. The struts are coupled together at the attachment openings.

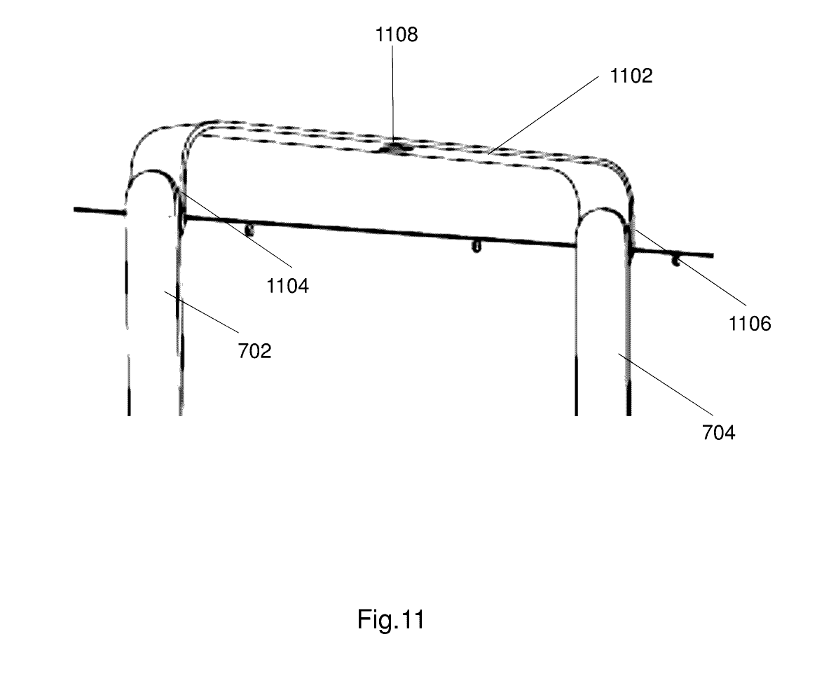

FIG. 11 shows a detailed view of the mounting arrangement 1100 of FIG. 7. The mounting arrangement 1100 comprises a bracket 1102. The bracket 1102, as shown in the embodiment of FIG. 11, is substantially U shaped. The bracket 1102 has a left end 1104 and a right end 1106. In the illustrated embodiment of FIG. 11, the bracket 1102 spans between the first strut 702 and second strut 704. The left end 1104 of the bracket 1102 is attached to the first end 706 of the first strut 702. The right end 1106 of the bracket 1102 is attached to the first end 710 of second strut 704. The bracket 1102 is removably attached to the first strut 702 and second strut 704. Each end of the bracket comprises an opening and slots as described in FIG. 10. The bracket 1102 is attached to each strut 702, 704 via a quick mount fastener or alternatively via a nut and bolt assembly. The bracket 1102 includes an orifice 1108. In the illustrated embodiment the orifice 1108 is located approximately in the centre of the bracket 1102. A hook can be coupled to the orifice 1108. The panel 100 can be hung or suspended from a structure, such as a beam or rafter, with the hook. Alternatively any suitable element or assembly can be connected to the bracket 1102 to allow the panel 100 to be hung from a structure. The bracket 1102 is formed from aluminium or stainless steel or any other suitable metal.

In an alternative embodiment the bracket 1102 can be coupled to the pegs 718, 720 that extend outwardly from opposing walls of the receptacle 801. The bracket 1102 can pivot relative to the pegs 718, 720. The pegs 718, 720 provide an alternative location to mount the bracket 1102, and suspend or hang the panel 100 from an appropriate structure or mount the panel to an appropriate structure. The bracket 1102 can only be attached to the pegs 718, 720 if the struts are removed.

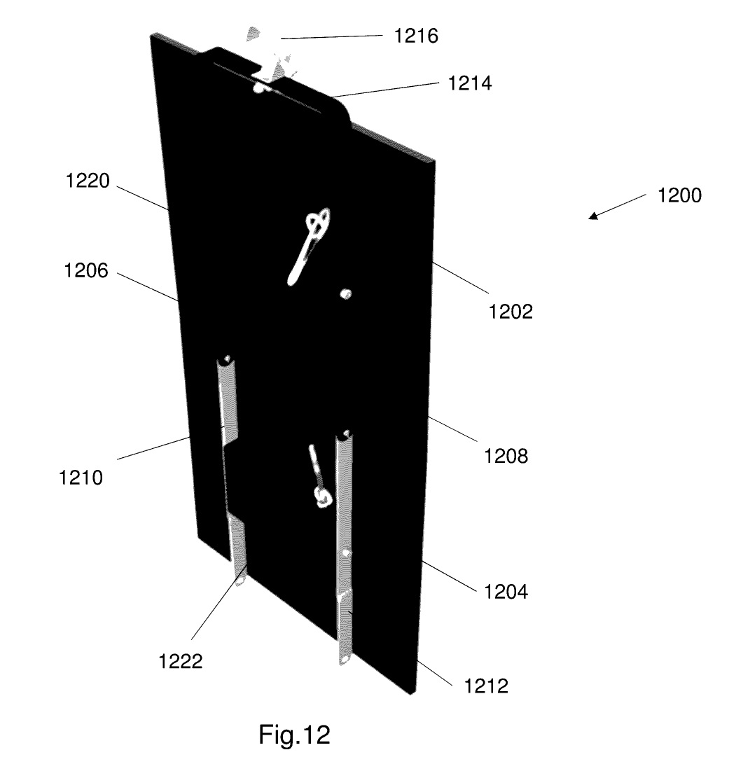

FIG. 12 illustrates an embodiment of a lighting system 1200. The lighting system 1200 comprises two or more lighting panels that are removably connected together. The lighting system 1200 is a modular system in that the size of the system 1200 can be changed by adding or removing lighting panels to the system. FIG. 12 shows a lighting system 1200 that comprises a first lighting panel 1202 and a second lighting panel 1204. Each lighting panel 1202 and 1204 is similar in construction as the lighting panel 100 as described with reference to FIGS. 1 to 11. The first lighting panel 1202 and second lighting panel 1204 each comprise a skeleton frame with a plurality of light emitting elements disposed on the skeleton frame. The light emitting elements are OLEDs. Each lighting panel 1202 and 1204 further comprises a controller disposed on each lighting panel to control the illumination of the OLEDs of each lighting panel 1202, 1204. Each lighting panel 1202, 1204, of the lighting system 1200 includes its own dedicated controller. The first lighting panel includes a controller 1220 disposed on the back of the first lighting panel 1202 and the second lighting panel includes a controller 1222 disposed on the back of the second lighting panel 1204. Each controller 1220, 1222 is arranged and configured to communicate with the OLEDs on the respective lighting panel.

An external source (not illustrated in FIG. 12 for clarity) can be used to control the illumination of the OLEDs of each lighting panel. The external source is in communication with each controller of each lighting panel 1202, 1204 in the lighting system 1200. The external source such as a laptop, tablet, computer, or smartphone includes appropriate software on the device that allows a user to provide data signals that encompass information regarding the specific OLEDs to illuminate, as described earlier, using any suitable protocol such as DMX or Artnet. The controller of each lighting panel 1202, 1204 of the lighting system 1200, allows a user to control each OLED individually through an external source. The controllers 1220, 1222 are a multi-channel controller that allows individual control of each OLED on each lighting panel 1202, 1204.

The lighting panels 1202, 1204 further include a coupling arrangement positioned on each lighting panel respectively. The coupling arrangement of each lighting panel 1202, 1204 include a plurality of struts that extend vertically. The coupling arrangement of each lighting panel 1202, 1204 is similar in structure to the coupling arrangement 700 as described above. The first lighting panel 1202 and the second lighting panel 1204 are removably connected to each other via the respective coupling arrangements of the first and second lighting panels 1202, 1204.

Referring to FIG. 12, the first lighting panel 1202 comprises a pair of struts 1206, 1208 disposed spaced from each other. The struts 1206, 1208 are attached to either side of the controller receptacle. The second lighting panel 1204 comprises a pair of struts 1210, 1212 disposed on either side of the controller receptacle of the second lighting panel 1204. The strut 1210 and 1212 are spaced apart from each other. The struts 1206, 1208 of the first lighting panel 1202, align with and removably couple with the respective struts 1210, 1212 of the second lighting panel 1204. The first strut 1206 of the first lighting panel 1202 removably couples to the first strut 1210 of the second lighting panel 1204. Similarly the second strut 1208 of the first lighting panel 1202 removably couples to the second strut 1212 of the second lighting panel 1204. Interconnecting the struts of the first lighting panel 1202 and the second lighting panel 1204 form the lighting system 1200. The struts of the first lighting panel 1202 and the second lighting panel 1204 are coupled together using a quick mount fastener or a nut and bolt assembly.

As per FIG. 12, the second lighting panel 1204 is positioned below the first lighting panel 1202 to form the lighting system 1200. The first lighting panel 1202 and second lighting panel 1204 are aligned vertically. A mounting arrangement is positioned on one of the lighting panels to mount the lighting system 1200 to an appropriate structure, such as a rafter or a wall or a beam etc. The mounting arrangement includes at least a bracket 1214. The bracket 1214 is a U shaped bracket and is similar in construction to the bracket 1102 as described in FIG. 11. The bracket 1214 includes the same features as bracket 1102. A swivelable hook 1216 can be attached to the bracket 1214 to mount the lighting system 1200 on to an appropriate structure. Other structures or mechanisms that allow mounting of the lighting system can also be connected to the bracket 1214.

In one embodiment up to eight lighting panels can be connected together via their respective coupling arrangements. The struts of all eight lighting panels can be interconnected sequentially to create a lighting system.

In one embodiment the struts of a single lighting panel may include a magnetic material or a magnetic metal disposed on the outer surfaces of the struts. The magnetic material causes the struts to be magnetized. The magnetic material creates a north pole on one strut and a south pole on the opposing strut. For example, referring the lighting panel 100, the first strut 702 has a north pole disposed on it and the second strut 704 has a south pole disposed on it. A similar arrangement can be applied to the struts of the lighting system 1200. Alternatively the material the strut is made from may be doped to create a north pole or south pole.

The magnetised struts allow for additional panels to be attached together in a horizontal direction, the panels being attached due to magnetic attraction between adjacent north and south poles. As described earlier the lighting panels of the lighting system are mechanically coupled to each other via respective struts in a vertical arrangement, the struts being removably coupled via fasteners. The system can comprise additional panels in a horizontal or transverse direction by attaching struts together via magnetic attraction.

In a further alternative embodiment a portion of the skeleton frame of a lighting panel, for example the longitudinal edges of the skeleton frame or body, of lighting panels may have a magnetic material disposed along the edges or the edges are locally doped, to create poles. A north pole is created on one longitudinal edge and a south pole is created on the opposite edge. Lighting panels can be removably coupled in a transverse or horizontal direction by magnetic attraction of adjacent north and south poles on the adjacent longitudinal edges of separate lighting panels. The magnetic material for example can be any ferric or ferrous material such as iron. The doping can be achieved by any suitable process.

In a further device the struts of the coupling arrangement may be telescoping. For example the struts 702, 704 of the lighting panel may be telescoping struts that are extendable in length. Each strut 702, 704, comprises a two or more elongate struts that are disposed in a nested arrangement. For example the first strut 702 includes an outer strut that functions as a sheath and houses an inner strut. The inner strut or a portion of the inner strut can be inserted into the outer strut. The inner strut can extend out from the outer strut to create a telescoping strut assembly. The inner strut is at least as long as or longer than the outer strut. The inner strut can be locked inside the outer strut by a locking member such as a removable pin or sprung tab on the inner strut that engages an aperture in the outer strut. The outer strut may include a plurality of apertures that are spaced apart from each other in a linear arrangement. The inner strut can be locked in various positions relative to the outer strut to allow varying levels of telescoping. The same structure described above with respect to strut 702, can be applied to strut 704 of the lighting panel 100. The struts of lighting panels 1202 and 1204 may have the same structure as described in the example referencing strut 702. The struts of each of the lighting panels 1202, 1204 in the lighting system 1200 may be telescoping. Telescoping struts allow for a greater adjustability for the lighting system 1200.

The telescoping struts provide greater options for spacing between lighting panels in a lighting system. The struts may also comprise multiple attachment openings that are disposed at varying locations along the strut, to allow for multiple attachment points along the strut. This provides greater flexibility and customisation for creating a lighting system 100.

In a further embodiment a power source may be disposed or attached to the mounting arrangement 1100 of the lighting panel 100. For example a power source such as a battery or a battery pack including multiple interconnected batteries may be attached to the mounting arrangement 1100. The battery or battery pack is attached to an underside of the bracket 1102. The struts 702, 704 can act as electrical conductors and conduct electricity to the controller 800, and in particular to the power unit 804. The struts 702, 704 act as voltage rails. One strut acts as a positive rail and the other strut acts a negative rail to provide power to the controller 800. This arrangement is advantageous because it provides a lighting panel 100 with an on-board power supply rather than using a power supply that is connected by wired connection. This allows for greater portability and usability in locations where a mains power source or an external power source may not be available.

In an embodiment the lighting system 1200 may comprise a power source such as a battery or battery pack. The power source is attached to or connected to the bracket 1214. The power source is also connected to the struts 1206, 1208 of the first lighting panel 1202. The struts 1206, 1208 may be formed from an electrically conductive material such as aluminium. The struts 1206, 1208 conduct electricity and function as voltage rails, in a similar manner as described above with respect to lighting panel 100. The struts 1210, 1212 of the second lighting panel 1204 are identical to the struts 1206, 1208 and also conduct electricity. The struts 1210, 1212 of the second lighting panel 1204 also function as voltage rails. The controllers 1220, 1222 of each respective lighting panel 1202, 1204 are in electrical communication with the respective struts, and receive power through the struts. The controllers 1220, 1222 of each respective lighting panel 1202, 1204 in the lighting system 1200 are connected in a parallel arrangement with the power source. A power source disposed on the mounting bracket 1214 provides an on-board power source which provides greater portability for the system 1200 and provides greater usability since the system 1200 can be used in locations where there is no mains power source.

The lighting panel 100 as described provides a number of advantages over at least some known lighting panel technology. The lighting panel 100 is substantially more light weight than at least some existing lighting panels. The overall weight of the lighting panel is less than 5 kg. The lighting panel 100 is substantially small in size. The lighting panel 100 has a volume of less than 0.0093 m³ and has approximate dimensions of 472 mm×472 mm×12 mm. The lighting panel 100 has a volume per unit of area of approximately 0.0042 m³, which is smaller than several known lighting panels such as the Jarag panel.

The lighting panel uses OLEDs as light emitting elements. This is advantageous because OLEDs consume less power than other lighting panels that use halogen lamps or traditional LEDs. The total power consumption of the lighting panel 100 is 23 Watts or less, as compared to known halogen lamp based lighting panel, known as the Jarag panel that consumes 1875 Watts. Each OLED pane 108a-108c consumes approximately 0.6 W as compared to traditional halogen lamps that consume approximately 75 Watts. The total power consumption of the lighting panel i.e. a panel that includes 64 OLEDs is 50 Watts or less, making the lighting panel 100 power efficient. OLEDs also are longer life light emitting elements. The lighting panel 100 has a lifetime of approximately 20,000 hours. OLEDs are more flexible and are occupy a smaller area than other light emitting element technologies such as Halogen lamps. Therefore more light emitting elements can be disposed on the lighting panel 100. The lighting panel 100 comprises 64 OLEDs in the illustrated example for a panel that has an area of 472 mm×472 mm. A similar sized panel would only occupy 25 halogen lamps or 49 LEDs.

The use of OLEDs in the lighting panel 100 is also advantageous because OLEDs produce a deeper colour display. The OLEDs 108a-108c of the lighting panel generate a warm light to day light output rather than a multi-colour display. The OLEDs 108a-108c produce a warm white light output.

In some alternative configurations OLEDs that generate a multi-colour display can be used in the lighting panel 100.

Further OLEDs do not produce UV light, and the lighting panel 100 is free of UV emission. UV light can cause wrinkles and attract insects. The current lighting panel 100 is free of such problems since there is no UV emission. OLEDs do not emit blue light risk, unlike traditional LEDs. OLEDs do not generate and emit blue light that can cause retinal damage. The OLEDs 108a-108c used on the lighting panel are advantageous because OLEDs produce light that is closest to sunlight or natural light that makes people feel more comfortable. OLEDs reduce glare as the light is generated by an electroluminescent layer as compared to halogens or traditional LEDs. OLEDs are a surface light source with reduced glare and shadow which further reduces the chances of retinal damage or discomfort to a person looking at the lighting panel 100. OLEDs 108a-108c further do not generate heat, particularly at the light surface, which makes the lighting panel safer and easier to handle. The total heat generation is low such that the surface temperature at the OLEDs, when active, is less than 35° C. This reduces the need for any heat sinks and diffusers and provides a smoother light output. The use of OLEDs in the lighting panel provides the added advantage of an increased beam angle of the light produced. OLEDs 108a-108c produce a light output having 180° beam angle and reduce any dead angle. OLEDs further produce a higher quality of light with only a minor amount of heat output. OLEDs have a high rendering index CRI of greater than 90, hence the lighting panel 100 and the output of the lighting panel looks better on camera as compared to lighting panels that use LEDs or halogen lamps. OLEDs further do not flicker as compared to traditional LEDs, and hence reduce the chance of irritation to viewers. OLEDs overall are cheaper to use and run, as compared to halogen lamps due to the reduced power consumption, thus making the lighting panel 100 cheaper to operate.

As described above the active surface of the OLEDs, of the lighting panel 100, is around 35 degrees. This low heat generation makes the lighting panel 100 particularly useful in indoor locations or closed rooms. The low heat output makes the lighting panel 100 particularly useful for stage lighting or studio lighting because there is a reduced chance of artists or audience members overheating. This provides a much more comfortable environment, as compared to using traditional lighting panels such as halogen based lighting panels, as the traditional lighting panels produce large amounts of heat.

The coupling arrangement 700 as used in the lighting panel 100 is advantageous because it allows a person to quickly connect and disconnect the lighting panel 100 to other lighting panels. The coupling arrangement, which comprises a pair of parallel struts is advantageous in the context of the lighting system 1200 because the struts provide a structure to create a modular system 1200. The lighting system 1200 is a modular lighting system, in which multiple lighting panels such as panels 1202 and 1204 can be removably coupled together. The struts provide locations for interconnection of a plurality of lighting panels. The attachment openings provided on the struts are keyed and include slots. The attachment openings are uniquely shaped such that identical lighting panels can be connected together by a quick fastening. The struts with the attachment openings provide a simple system to interconnect a plurality of lighting panels together to create a lighting system of a desired size and dimension.

The lighting system 1200 provides similar advantages as the ones listed above with reference to the lighting panel 100, because the lighting system 1200 comprises two or more lighting panels 1202, 1204 that are of the same construction as the lighting panel 100.

Each lighting panel in the system comprises its own multichannel controller. This allows a user to control each OLED of each lighting panel individually. The controller allows for customized output on the OLEDs of the lighting panels of the lighting system.

The mounting arrangement, in particular the bracket, is advantageous because it allows for easy and quick mounting on a wide range of structures. The bracket and mounting hook allows the lighting panel and lighting system to be hung vertically. The bracket provides a wide range of mounting options and allows the lighting panel and the lighting system to be used in a number of different operating conditions.

The lighting panel 100 and the lighting system 1200 as described, is suited for use in exhibition lighting. For example the lighting panel 100 and lighting system 1200 are suited for use in stage lighting, studio lighting, film lighting, art gallery lighting, entertainment lighting and performance lighting. The lighting system 1200 and lighting panel 100 are also useful in lighting public places such as walkways, hallways, rooms, entrances and other places where there is generally large foot traffic. The lighting panel 100 and lighting system 1200 are useful as billboards and message boards due to some of the other advantages as described herein. Other applications are also contemplated.

The modular nature of the lighting system 1200 makes the lighting system particularly useful for use in entertainment and lighting applications. The assembly and disassembly of the lighting system 1200 is easy because the struts are aligned along the attached openings, and the struts are fastened together with a fastener. The lighting system 1200 is intuitive to use.

Where, in the foregoing description reference has been made to integers or components having known equivalents thereof, those integers or components are herein incorporated as if individually set forth.

It will be appreciated by persons skilled in the art that numerous variations and/or modifications may be made to the specific embodiments, described herein, without departing from the spirit or scope of the disclosure as broadly described. The present embodiments are, therefore, to be considered in all respects as illustrative and not restrictive. Although the present disclosure has been described in terms of certain embodiments, other embodiments apparent to those of ordinary skill in the art also are within the scope of this disclosure.

Thus, various changes and modifications may be made without departing from the spirit and scope of the disclosure. For instance, various components may be repositioned as desired. Moreover, not all of the features, aspects and advantages are necessarily required to practice the present disclosure. Accordingly, the scope of the present disclosure is intended to be defined only by the claims that follow.

Reference to any prior art in this specification is not, and should not be taken as, an acknowledgement or any form of suggestion that that prior art forms part of the common general knowledge in the field of endeavour in any country in the world.

1. A lighting panel comprising:
a body, the body comprising a first side and a second side, the first and second sides being opposed to each other,
the body including a skeleton frame, the skeleton frame including a plurality of openings,
one or more light emitting elements positioned on the first side of the body and on the skeleton frame, each of the one or more light emitting elements positioned within one of the plurality of openings,
the one or more light emitting elements are solid state light emitting devices,
a controller in electronic communication with the one or more light emitting elements, the controller configured to receive a control signal, process the received control signal and provide an illumination signal to the one or more light emitting elements to individually activate the one or more light emitting elements, and
a coupling arrangement positioned on the second side of the body, the coupling arrangement structured to allow removable connection with another lighting panel.

2. A lighting panel in accordance with claim 1, wherein the light emitting elements are arranged in matrix comprising two or more rows of light emitting elements and two or more columns of light emitting elements.

3. A lighting panel in accordance with claim 1, wherein the panel comprises a total of sixty four light emitting elements arranged in the matrix, the one or more light emitting elements being arranged in an 8×8 matrix arrangement.

4. A lighting panel in accordance with claim 1, wherein the light emitting elements are arranged such that the beam angle of light generated by the light emitting elements is least 180°.

5. A lighting panel in accordance with claim 1, wherein the solid state light emitting devices are organic light emitting diodes.

6. A lighting panel in accordance with claim 1, wherein the coupling arrangement comprises one or more elongate struts, the one or more elongate struts being disposed on a second side of the body.

7. A lighting panel in accordance with claim 1, wherein the coupling arrangement comprises a first strut and a second strut, each strut being disposed on the second side of the body, the second strut being spaced from the first strut, each of the first strut and second strut including an attachment opening located at each end of each of the first strut and the second strut.

8. A lighting panel in accordance with claim 7, wherein the attachment opening comprising a pair of slots, each slot of the pair of slots extending outwardly from the attachment opening, each slot of the pair of slots extending in an opposite direction to the other slot of the pair of slots.

9. A lighting panel in accordance with claim 7, wherein the first strut includes two attachment openings, the second strut includes two attachment openings, the attachment openings on the first strut aligns with the attachment openings on the second strut.

10. A lighting panel in accordance with claim 7, wherein the first strut and the second strut are telescoping, such that the first strut and second strut are length extendable.

11. A lighting panel in accordance with claim 7, wherein the first strut and the second strut include a magnetic material disposed on the first strut and the second strut respectively.

12. A lighting panel in accordance with claim 1, wherein the panel comprises a mounting arrangement, the mounting arrangement shaped and configured to allow the panel to be mounted to a structure.

13. A lighting panel in accordance with claim 12, wherein the mounting arrangement is removably connected to the coupling arrangement.

14. A lighting panel in accordance with claim 13, wherein the mounting arrangement comprises a U shaped bracket, the U shaped bracket comprises an orifice and a swivelable hook, the swivelable hook connected to the orifice and the swivelable hook configured to mount the panel on a structure.

15. A lighting panel in accordance with claim 14, wherein the U shaped bracket is removably connected to the first strut and second strut, the U shaped bracket is removably connected to the first strut and the second strut via a fastener.

16. A lighting panel in accordance with claim 1, wherein the controller comprises a data unit, a power unit and an interface unit, the data unit generating and providing an illumination signal to the one or more light emitting elements, the power unit generating and providing a power signal to the one or more light emitting elements.

17. A lighting panel in accordance with claim 16, wherein the controller comprises one or more data ports, the one or more data ports receive a data signal from an external source, the data signal encompassing information to illuminate one or more of the light emitting elements, the controller comprises one or more power ports, the one or more power ports receive a power signal from a power source.

18. A lighting panel in accordance with claim 16, wherein the data unit receiving the data signal and converting the data signal to the illumination signal.

19. A lighting panel in accordance with claim 1, wherein the lighting panel comprises a receptacle disposed on the second side, the receptacle housing and holding the controller within the receptacle.

20. A lighting panel in accordance with claim 6, wherein the first strut and second strut are connected to either side of the receptacle, the lighting panel comprises a pair of pegs, each peg of the pair of pegs connected to the receptacle and extending outwardly from the receptacle, the first strut and second strut connected to one of the pegs of the pair of pegs.

21. A lighting panel in accordance with claim 1, wherein the lighting panel weighs 5 kg or less, and the lighting panel comprises a volume of less than 0.0093 m³.

22. A lighting panel in accordance with claim 1, wherein the lighting panel is useful for exhibition lighting or stage lighting.

23. A lighting system comprising;
two or more lighting panels, each lighting panel comprising one or more solid state light emitting elements, each lighting panel is as per claim 1,
the lighting system is a modular system such that each lighting panel of two or more lighting panels, being removably connectable to one or more other lighting panels.

24. A lighting system in accordance with claim 23, wherein the lighting system comprises a controller assembly configured to control a light emitting element via a multichannel controller, wherein the multichannel controller comprises a plurality of control channels and each channel corresponding to each light emitting element.

25. A lighting system in accordance with claim 23, wherein each lighting panel comprises a pair of struts, the struts including one or more attachment openings, the struts of each lighting panel being removably connectable to each other.
